(19) United States
(12) Patent Application Publication
(10) Pub. No.: US 2005/0157766 A1
(43) Pub. Date: Jul. 21, 2005

(54) Semiconductor optical device including spot size conversion region

(76) Inventors: Hyeon-Soo Kim, Suwon-si (KR); Young-Churl Bang, Suwon-si (KR); Jung-Kee Lee, Suwon-si (KR); Eun-Hwa Lee, Suwon-si (KR); Jun-Youn Kim, Suwon-si (KR)

Correspondence Address: CHA & REITER, LLC, 210 ROUTE 4 EAST STE 103, PARAMUS, NJ, 07652, US

(21) Appl. No.: 10/864,059

(22) Filed: Jun. 9, 2004

(30) Foreign Application Priority Data
Jan. 19, 2004 (KR) 2004-3694

(51) Int. Cl. H01S 5/00

(52) U.S. Cl. 372/43

(57) ABSTRACT

A semiconductor optical device including an SSC region includes a semiconductor substrate, a lower clad layer grown on the semiconductor substrate, and an upper clad layer grown on the lower clad layer. The semiconductor optical device with an SSC (Spot Size Conversion) area includes a gain area including an active layer grown between the lower clad layer and the upper clad layer to generate/amplify an optical signal; and an SSC (Spot Size Conversion) area including a waveguide layer extended from the active layer positioned between the lower and upper clad layers, such that it performs a spot size conversion (SSC) process of the optical signal generated from the gain area and generates the SSC-processed optical signal. The waveguide layer of the SSC area is configured to gradually reduce its thickness in proportion to a distance from the active layer, and the upper clad layer is etched in the form of a taper structure such that the taper structure has a narrower width in proportion to a distance from one end of the semiconductor optical device having the gain area to the other end of the semiconductor optical device having the SSC area.

### CLAIM OF PRIORITY

This application claims priority to an application entitled “SEMICONDUCTOR OPTICAL DEVICE INCLUDING SPOT SIZE CONVERSION REGION,” filed in the Korean Intellectual Property Office on Jan. 19, 2004 and assigned Serial No. 2004-3694, the contents of which are hereby incorporated by reference.

### BACKGROUND OF THE INVENTION

1. Field of the Invention

The present invention relates to a semiconductor optical device, and more particularly to a semiconductor optical having a spot size converter (SSC) integrated therein.

2. Description of the Related Art

In recent times, a semiconductor laser has been widely adapted as a light source for used in optical networks and a variety of optical media. The semiconductor laser has a high output power and a small-sized configuration, so that it can be adapted as a light source in various ways.

However, the semiconductor laser has drawbacks in connecting its output optical signal with a transmission media, for example, a single-mode optical fiber and an optical waveguide, due to a high-coupling loss between the output optical signal and the transmission media. The high-coupling loss is caused by a difference between the output optical single mode of the semiconductor laser and the single-mode optical fiber mode or the optical waveguide mode.

To solve the aforementioned problems, there has been newly developed a spot size converter (SSC) or a lens system for coupling the optical signal with either the single-mode optical fiber or the optical waveguide. The lens system may use a collimator lens for collimating the output optical signal of the semiconductor laser and a focusing lens for focusing the collimated optical signal on the single-mode optical fiber or the optical waveguide, etc.

However, the lens system is large and difficult to align its optical axis and acquiring a constant production yield. In contrast, the SSC can be integrated on the same substrate as the semiconductor optical device such as the semiconductor laser, etc., resulting in a reduced number of fabrication processes, lower production costs, and a minimum volume of an overall system.

The SSC must confine the optical signal generated from a light source device such as a semiconductor laser, etc., in an active layer of the semiconductor laser. A confinement degree of the optical signal in the active layer is known as an optical confinement factor. The SSC is capable of increasing the optical confinement factor of the semiconductor optical device, thus resulting in a lower threshold current of the semiconductor laser. The SSC gradually emits the optical signal confined in the active layer of the semiconductor laser to increase the magnitude of the optical signal at an output interface of the semiconductor optical device, thereby providing a minimum coupling loss of the optical signal when coupled to either other optical elements or transmission media.

A representative semiconductor optical device in which the SSC is integrated has been disclosed in U.S. Pat. No. 6,018,539, entitled “Semiconductor Laser and Method of Fabricating Semiconductor Laser”, filed by Kimura et al., and in U.S. Pat. No. 5,737,474, entitled “Semiconductor Optical Device”, field by Aoki et al.

U.S. Pat. No. 6,018,539 proposed by Kimura has disclosed a semiconductor optical device in which a vertically-titled SSC is integrated. The semiconductor optical device having the SSC in U.S. Pat. No. 6,018,539 proposed by Kimura uses a growth method such as a Selective Area Growth (SAG) method, so that it can form an SSC tilted in a vertical direction different from that of the semiconductor laser. Further, higher the TEF (Thickness Enhancement Factor) between a waveguide layer of the vertically-tilted SSC and the optical device area, the larger the mode-coupling effect caused by the SSC grown by the SAG method.

U.S. Pat. No. 5,737,474 proposed by Aoki has disclosed a semiconductor optical device in which both ends of an upper clad positioned in the SSC region are tilted. In Aoki, a high refractive index difference occurs between the semiconductor optical device and the atmosphere surrounding the semiconductor optical device, thus resulting in an increased radiation angle.

The conventional semiconductor optical device includes a successively-structured active layer ranging from one area where the SSC is formed using the SAG method and a gain area containing a light source such as a semiconductor laser. Also, other semiconductor optical device in which an area where the SSC is formed using a Butt joint method and a gain area containing a light source such as a semiconductor laser are formed discontinuously must have a predetermined thickness ratio of at least 3:1, which is indicative of the ratio of an SSC thickness to a gain area thickness to implement ideal operation characteristics. Further, the optical device must allow a stress difference between the SSC area and the gain area to be a predetermined value of less than 1%.

However, if the thickness ratio between the SSC area and the gain area is higher than the ratio of 3:1, a stress difference between the SSC area grown by either the SAG method or the Butt joint method and the gain area increases, such that it deteriorates the optical output characteristics whereas it enhances the SSC characteristic.

### SUMMARY OF THE INVENTION

Therefore, the present invention has been made in view of the above problems and provides additional advantages, by providing a semiconductor optical device in which an SSC area provides excellent mode-coupling effects and high output-light efficiency.

In accordance with the present invention, a semiconductor optical device includes a semiconductor substrate, a lower clad layer grown on the semiconductor substrate, and an upper clad layer grown on the lower clad layer. The semiconductor optical device having an SSC (Spot Size Conversion) area further includes: a gain area including an active layer grown between the lower clad layer and the upper clad layer to generate/amplify an optical signal; and an SSC (Spot Size Conversion) area including a waveguide layer extended from the active layer positioned between the lower and upper clad layers, such that it performs a spot size conversion (SSC) process of the optical signal generated from the gain area and generates the SSC-processed optical signal, wherein the waveguide layer of the SSC area is configured to gradually reduce its thickness in proportion to a distance from the active layer, and the upper clad layer is etched in the form of a taper structure such that the taper structure has a narrower width in proportion to a distance from one end of the semiconductor optical device having the gain area to the other end of the semiconductor optical device having the SSC area.

### BRIEF DESCRIPTION OF THE DRAWINGS

The above features and other advantages of the present invention will be more clearly understood from the following detailed description taken in conjunction with the accompanying drawings, in which:

FIG. 1 is a perspective view illustrating a semiconductor optical device in accordance with a preferred embodiment of the present invention;

FIG. 2 is a plan view illustrating the semiconductor optical device shown in FIG. 1 in accordance with a preferred embodiment of the present invention; and

FIG. 3 is a cross-sectional view illustrating the semiconductor optical device taken along the A-A′ line of FIG. 1 in accordance with a preferred embodiment of the present invention.

### DETAILED DESCRIPTION

Now, embodiments of the present invention will be described in detail with reference to the annexed drawings. In the drawings, the same or similar elements are denoted by the same reference numerals even though they are depicted in different drawings. For the purposes of clarity and simplicity, a detailed description of known functions and configurations incorporated herein will be omitted as it may make the subject matter of the present invention unclear.

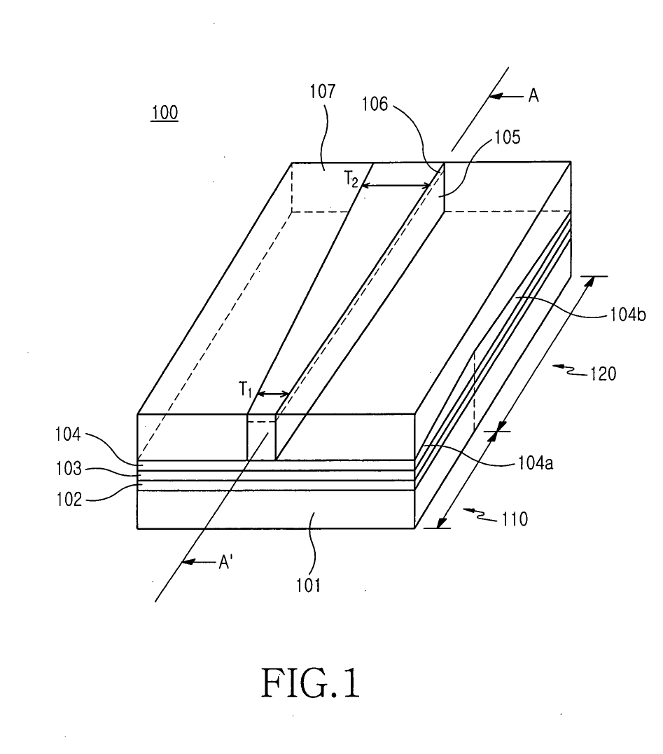

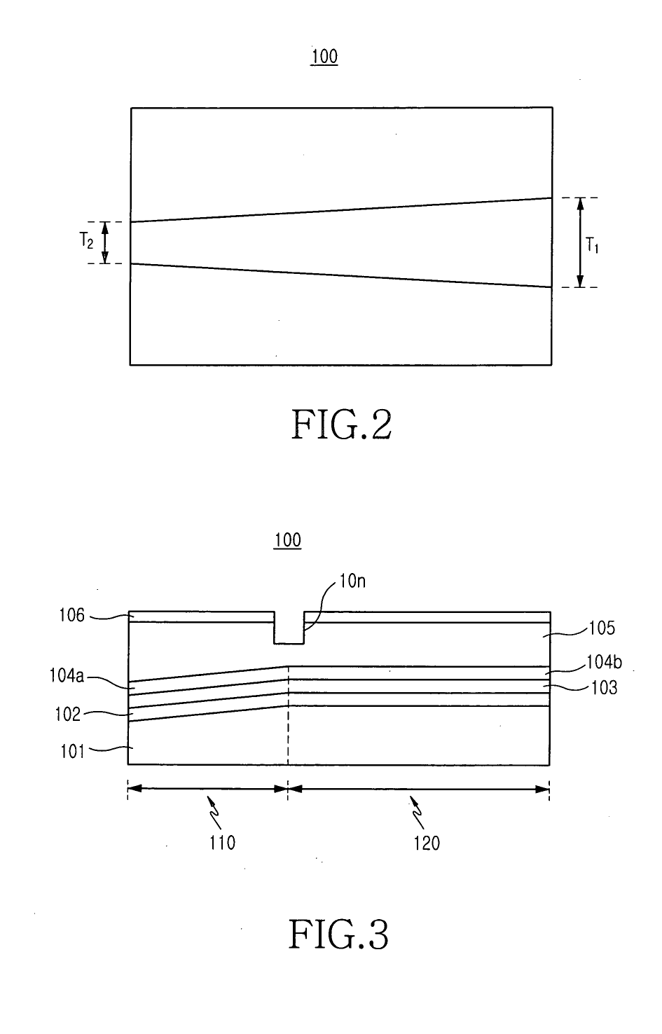

Referring to FIGS. 1 to 3, the semiconductor optical device 100 according to the present invention includes a gain area 120 and an SSC (Spot Size Conversion) area 110.

The gain area 120 includes a semiconductor substrate 101, a buffer layer 102 grown on the semiconductor substrate 101, a lower clad layer 103 grown on the buffer layer 102, an upper clad layer 105 grown on the lower clad layer 103, and a contact layer 106 grown on the upper clad layer 105, etc., and also includes an active layer 104b grown between the lower and upper clad layers 103 and 105 to produce/amplify an optical signal.

The SSC area 110 includes a waveguide area 104a extended from the active layer 104b positioned between the lower and upper clad layers 103 and 105. The semiconductor optical device 100 deposits the contact layer 106 only on the gain area 120 or deposits the contact layer 106 on the SSC area 110 in order to electrically separate the SSC area 110 from the gain area 120, such that it can be applied to another application structure in which a trench 107 is formed between the SSC area 110 and the gain area 120.

The upper clad layer 105 is etched in the form of a taper structure, such that the taper structure has a narrower width in proportion to a distance from one end of the semiconductor optical device 100 having the gain area 120 to the other end of the semiconductor optical device 100 having the SSC area 110. Note that the longer the distance from one end to the other end of the semiconductor optical device 100, the narrower the width of the taper structure. For example, the upper clad layer 105 is etched in the form of a taper structure which has a width T₂ of 2˜5 μm at one end of the semiconductor optical device 100 including the gain area 104b, whereas it has a width T₁ of less than 2.0 μm at the other end of the semiconductor optical device 100 including the SSC area 104a.

The gain area 120 includes an active layer 104b grown between the upper and lower clad layers 103 and 105. The active layer 104b may include all the compound semiconductor layers, for example, InGaAsP, AlGaInAs, InP, and GaAs, etc. A variety of semiconductor optical devices, such as a semiconductor laser for generating an optical signal of a predetermined wavelength, a semiconductor optical amplifier (SOA) for amplifying an entry optical signal, and a modulator for modulating the entry optical signal into another optical signal loading data on the entry optical signal may be integrated in the gain area 120 according to the operation characteristics of the active layer 104b. Note that an AlGaInAs-based compound semiconductor layer is oxidized in air, such that it is difficult to apply it to a burried-hetero-structured semiconductor optical device other than a ridge-structured semiconductor optical device. However, the present invention can be applied to the ridge-structured semiconductor optical device, so that it can also be applied to the AlGaInAs-based compound semiconductor layer.

The SSC area 110 further includes a waveguide layer 104a extended from the active layer 104b, and is grown by the SAG method to implement a TEF (Thickness Enhancement Factor) of the same or less than 2:1 compared to the active layer 104b. The waveguide layer 104a may use a material having a refractive index lower than those of the upper and lower clad layers. The waveguide layer 104a of the SSC area 110 has a narrower thickness in proportion to the distance from the active layer 104b.

The operation characteristics of the semiconductor optical device 100 are compared with those of a general semiconductor optical amplifier as shown in the following Table 1. In particular, Table 1 illustrates the comparison result between output characteristics of the semiconductor optical devices and other output characteristics of a conventional semiconductor optical device. In this example, the semiconductor optical device 100 has an overall length of 600 μm, the SSC area 110 has a length of 150 μm, and the gain area 120 has a length of 450 μm. The upper clad layer 105 has a width of 3 μm at one end of the semiconductor optical device 100 including the gain area 120 and a width of 1 μm at the other end of the semiconductor optical device 100 including the SSC area 110.

TABLE 1

| | | | | |
|---|---|---|---|---|
| | | | SE | FFPH/FFPV |
| Category | TEF | ITH(mA) | (w/A) | (median) |

| | | | | | |
|---|---|---|---|---|---|
| 1 | Semiconductor | 2.3 | 55 | 0.13 | 18/15 |
| | optical device | | | | |
| | of Kimura et al. | | | | |
| 2 | Semiconductor | | 20 | 140.30 | 24/44 |
| | conductor | | | | |
| | optical device | | | | |
| | of Aoki et al. | | | | |
| 3 | Semiconductor | 1.5 | 40 | 0.21 | /13 |
| | optical device | | | | |
| | of the present | | | | |
| | invention | | | | |

Referring to Table 1, if the TEF is higher than 2.3, the semiconductor optical device increases a threshold value denoted by ITH and output efficiency denoted by SE but reduces a radiation angle of an output optical signal to less than 20°. In contrast, the semiconductor optical device including a laterally-tapered upper clad layer as in Aoki's semiconductor optical device scarcely reduces a radiation angle of an output optical signal, but it has excellent laser efficiency such as ITH or SE.

The TEF is indicative of a thickness difference between the SCC area and the gain area of the semiconductor optical device. The semiconductor optical device having a TEF of less than 1.5 according to the present invention implements a lower ITH value, a higher SE value, and a lower radiation angle as compared to the conventional semiconductor optical device proposed by Kimura et al.

As apparent from the above description, the present invention provides a semiconductor optical device tilted in vertical and lateral directions, such that it can also be applied to a structure having a TEF lower than the conventional semiconductor optical device. In other words, the present invention reduces the TEF value, such that it can satisfy the operation characteristics of the SCC area and the other operation characteristics of the gain area such as a semiconductor laser at the same time. Furthermore, the present invention can also be applied to a semiconductor optical device which is difficult to apply it to a burried-hetero structure, such as a semiconductor optical device including an AlGaInAs-based active layer.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

1. In a semiconductor optical device including a semiconductor substrate, a lower clad layer grown on the semiconductor substrate, and an upper clad layer grown on the lower clad layer, the semiconductor optical device comprising:
a gain area having an active layer grown between the lower clad layer and the upper clad layer to generate/amplify an optical signal; and
an SSC (Spot Size Conversion) area having a waveguide layer extended from the active layer positioned between the lower and upper clad layers, such that it performs a spot size conversion (SSC) process of the optical signal generated from the gain area and generates the SSC-processed optical signal,
wherein the waveguide layer of the SSC area is configured to gradually reduce its thickness in proportion to a distance from the active layer, and the upper clad layer is etched in the form of a taper structure such that the taper structure has a narrower width in proportion to a distance from one end of the semiconductor optical device having the gain area to the other end of the semiconductor optical device having the SSC area.

2. The semiconductor optical device as set forth in claim 1, wherein the waveguide layer of the SSC area is grown by a Selective Area Growth (SAG) method to implement a predetermined TEF (Thickness Enhancement Factor) of 2:0˜2:1.

3. The semiconductor optical device as set forth in claim 1, wherein the upper clad layer is etched in the form of a taper structure which has a width of 2˜5 μm at one end of the semiconductor optical device including the gain area and a width of less than 0˜2.0 μm at the other end of the semiconductor optical device including the SSC area.

4. The semiconductor optical device as set forth in claim 1, further comprising:
a trench area for optically separating the SSC area from the gain area.

5. The semiconductor optical device as set forth in claim 1, wherein the gain area is indicative of a semiconductor laser for generating an optical signal of a predetermined wavelength.

6. The semiconductor optical device as set forth in claim 1, wherein the gain area is indicative of a semiconductor optical amplifier for amplifying an entry optical signal.

7. The semiconductor optical device as set forth in claim 1, wherein the gain area is indicative of an optical modulator for modulating an entry optical signal into another optical signal for loading data on the entry optical signal.

8. The semiconductor optical device as set forth in claim 1, wherein the active layer includes compound semiconductor materials based on InGaAsP, AlGaInAs, InP, and GaAs.

9. The semiconductor optical device as set forth in claim 1, wherein the semiconductor optical device is configured in the form of a ridge.
